(19) United States
(12) Patent Application Publication
(10) Pub. No.: US 2021/0151349 A1
(43) Pub. Date: May 20, 2021

(54) SEMICONDUCTOR STRUCTURE AND MANUFACTURING METHOD THEREOF

(71) Applicant: Shanghai Huali Integrated Circuit Mfg. Co., Ltd., Shanghai (CN)

(72) Inventor: Nianheng ZHANG, Shanghai (CN)

(21) Appl. No.: 16/684,553

(22) Filed: Nov. 14, 2019

(51) Int. Cl. H01L 21/768; H01L 21/3213; H01L 21/308

(52) U.S. Cl. CPC H01L 21/76804; H01L 21/3081; H01L 21/32135

(57) ABSTRACT

The present disclosure provides a semiconductor structure and a manufacturing method thereof. The semiconductor structure includes a VIA going throughout the dielectric layer along a height direction of the semiconductor structure. The VIA interconnects the front device of the semiconductor structure and the back metal wire of the semiconductor structure. By performing a first etching process and a second etching process, a first dimension of the cross section of the VIA orthogonal to the height direction in an extending direction of the above-mentioned back metal wire is greater than a second dimension in an direction vertical to the extending direction. By forming the VIA using the manufacturing method of the present disclosure, the feature size of the second direction of the VIA can be kept unchanged without modifying the mask.

### CROSS-REFERENCES TO RELATED APPLICATIONS

The present application claims priority to Chinese Patent Application No. 201811637245.X, filed on Dec. 29, 2018, entitled “SEMICONDUCTOR STRUCTURE AND MANUFACTURING METHOD THEREOF”, which is incorporated by reference herein for all purposes.

### FIELD

The present disclosure relates to a semiconductor structure and a method of fabricating the same, and in particular to a VIA structure and a method of fabricating the same.

### BACKGROUND

Since the disclosure of integrated circuits by Dr. Jack Kilby of Texas Instruments in early years, scientists and engineers have made numerous disclosures and improvements in semiconductor devices and processes. Over 50 years, the dimensions of semiconductors have been significantly reduced, which translates into an increasing processing speed and decreasing power consumption. To date, the development of semiconductors has largely followed Moore's Law, which roughly states that the number of transistors in dense integrated circuits doubles about every two years. At present, semiconductor processes are developing toward below 20 nm, and some companies are embarking on 14 nm processes. Just to provide a reference herein, a silicon atom is about 0.2 nm, which means that the distance between two separate components manufactured by a 20 nm process is about only one hundred silicon atoms. Semiconductor device manufacturing has therefore become increasingly challenging and advancing toward the physically possible limit.

How to improve the performance of 28 nm semiconductor devices has become a top priority in the semiconductor manufacturing industry, and it is also a huge challenge. At present, the performance of a 28 nm semiconductor device can be improved by reducing the resistance of a Kelvin VIA in the metal layer of the back surface of the semiconductor device. Amplifying the feature size (also known as CD, Critical Dimension)) of the Kelvin VIA is considered to be an effective method in reducing the resistance of the Kelvin VIA.

However, as previously mentioned, in the case where the feature sizes of the semiconductor devices are increasingly shrinking, the feature size of the enlarged Kelvin VIAs means the possibility of short circuiting with the Kelvin VIAs and other VIAs or metal wires in the back metal layer is greatly increased, resulting in a decrease in the yield of the semiconductor device.

Furthermore, it is the most common practice to modify the layout of the device by modifying the mask to achieve a method of amplifying the feature size of the Kelvin VIA. However, since the particularity of the Kelvin VIA position that is located in a turning area, changing the feature size of a Kelvin VIA requires extensive modification of the layout of the entire semiconductor device, to increase the cost of the semiconductor device manufacturing process.

Therefore, there is a need for a method of fabricating a semiconductor structure that can reduce the resistance of the Kelvin VIA by changing the feature size of the Kelvin VIA without changing the mask. At the same time, the appearance of the Kelvin VIA fabricated by the above manufacturing method does not increase the possibility of short circuiting with other VIAs or metal lines in the back metal layer to ensure the yield of the semiconductor structure.

### SUMMARY

A brief summary on one or more aspects is given below to provide the basic understanding for these aspects. This summary is not an exhaustive overview of all the contemplated aspects and is neither intended to indicate critical or decisive elements of all aspects nor to attempt to define the scope of any or all aspects. Its sole purpose is to present some concepts of one or more aspects in a simplified form as a preface for a more detailed description presented later.

As described above, in order to solve the above problems, the present disclosure provides a method of manufacturing a semiconductor structure for forming a VIA going throughout a dielectric layer along a height direction of the semiconductor structure, the method of manufacturing comprising:

providing a substrate, and a front device of the semiconductor structure is formed in the substrate, the front device is electrically connected to a back metal wire of the semiconductor structure through the VIA, and an upper portion of the substrate is formed with the dielectric layer covering the substrate; performing a first etching process in a position corresponding to the front device, the first etching process forms a partial VIA in an upper portion of the dielectric layer; and performing a second etching process, the second etching process enable the VIA go throughout the dielectric layer in the height direction to expose the front device, and a first dimension of the cross section of the formed VIA orthogonal to the height direction in an extending direction of the above-mentioned back metal wire is greater than a second dimension in an direction vertical to the extending direction by performing the first etching process and the second etching process.

In the above embodiment, the first etching process comprises using a gas combination comprising CF4 gas, and the CF4 gas accounts for 20-35% of the gas combination.

In the above embodiment, the CF4 gas accounts for 28% of the gas combination.

In the above embodiment, the second etching process comprises setting the dissociation power of the etching gas to 270-350 W.

In the above embodiment, the set dissociation power is 280-330 W.

In the above embodiment, the dissociation of the set power 300 W.

In the above embodiment, said second etching process comprises using a gas combination comprising CF4 gas, and the CF4 gas accounts for 25-40% of the gas combination.

In the above embodiment, the CF4 gas accounts for 35% of the gas combination.

In the above embodiment, a ratio of the first dimension to the second dimension is greater than 1.2.

In the above embodiment, the ratio of the first dimension to the second dimension is 1.2-1.5.

In the above embodiment, performing the second etching process further comprises forming a trench in an upper portion of the dielectric layer, and the back metal wire is formed in the trench; and the manufacturing method further comprises forming a patterned hard mask layer on an upper surface of the dielectric layer before performing the second etching process, the patterned hard mask layer defining an etching pattern of the trench.

In the above embodiment, the hard mask layer is a metal mask, and/or the hard mask layer is made of TiN.

In the above embodiment, and a ratio of the first dimension to the second dimension is 1.5-1.8.

The disclosure also provides a semiconductor structure including a VIA going throughout a dielectric layer in a height direction of the semiconductor structure, the VIA interconnecting a front device of the semiconductor structure and a back metal wire of the semiconductor structure, a first dimension of the cross section of the VIA orthogonal to the height direction in an extending direction of the back metal wire is larger than a second dimension in an direction vertical to the extending direction.

In the above embodiment, a ratio of the first dimension to the second dimension is greater than 1.2.

In the above embodiment, the ratio of the first dimension to the second dimension is 1.2-1.5.

In the above embodiment, the ratio of the first dimension to the second dimension is 1.5-1.8.

According to the semiconductor structure and the method of fabricating the same provided by the present disclosure, the feature size of the VIA is increased by adjusting the etching process, and the cross-section of the VIA is maintained in one direction larger than the other in the vertical direction. Therefore, short circuit between the VIA and other VIAs or metal lines is not caused due to the increase of the feature size, to ensure the yield of the semiconductor structure.

### BRIEF DESCRIPTION OF THE DRAWINGS

FIGS. 1-8 show the schematic structure of a semiconductor in a manufacturing process of the manufacturing method provided by the present disclosure.

FIG. 9A shows a top plan view of a VIA provided by the present disclosure.

FIG. 9B shows a schematic cross-sectional view of FIG. 9A in the plane AA′.

FIG. 9C shows a schematic cross-sectional view of FIG. 9A in the plane BB′.

FIG. 10A is a view showing a comparison of the VIA resistance value produced by the manufacturing method provided by the present disclosure and the VIA resistance value manufactured by the prior art.

FIG. 10B is a graphical illustration of a comparison of yields of device manufactured by the manufacturing methods provided by the present disclosure and by the prior art.

### REFERENCE SIGNS

100 Substrate
110 Active area
200 NDC layer
300 TEOS layer
400 Dielectric layer
500 NDC layer
600 NFDARC layer
700 Hard mask layer
800 Oxide layer
900 BARC layer
901 Photo-resist layer
910 Barrier layer
911 SIARC layer
912 Photo-resist layer

### DETAILED DESCRIPTION

The following description is presented to enable one of ordinary skill in the art to implement and use the present disclosure and incorporate it into the context of a particular application. Various modifications, as well as various usages in various applications, will be readily apparent to those skilled in the art, and the generic principles defined herein may be applicable to a wide range of embodiments. Thus, the present disclosure is not limited to the embodiments presented herein, but rather should be given its broadest scope consistent with the principles and novel features disclosed herein.

In the following detailed description, numerous specific details are set forth to provide a more thorough understanding of the present disclosure. However, it will be apparent to those skilled in the art that the present disclosure may be practiced without limitations from these specific details. In other words, well-known structures and devices are shown in a block diagram form and are not shown in detail, to avoid obscuring the present disclosure.

The reader is cautioned as to all files and documents which are filed at the same time as this specification and which are open for the public to consult, and the contents of all such files and documents are incorporated herein by reference. Unless directly stated otherwise, all features disclosed in this specification (including any of the appended claims, the abstract, and the accompanying drawings) may be replaced by alternative features serving the same, equivalent, or similar purposes. Therefore, unless expressly stated otherwise, each of the features disclosed is only one example of a group of equivalent or similar features.

Note that when used, the flags left, right, front, back, top, bottom, front, back, clockwise, and counter-clockwise are used for convenience purposes only and do not imply any specific fixed direction. In fact, they are used to reflect the relative position and/or direction between various parts of an object.

As used herein, the terms “over . . . “under . . . ”, “between . . . and . . . ”, and “on . . . ” means the relative position of that layer relative to another layer. Likewise, for example, a layer that is deposited or placed over or under another layer may be in direct contact with another layer or there may be one or more intervening layers. In addition, a layer that is deposited or placed between layers may be in direct contact with the layers or there may be one or more intervening layers. In contrast, a first layer “on” a second layer is in contact with the second layer. In addition, a relative position of a layer relative to another layer is provided (assuming that film operations of deposition, modification, and removal are performed in relative to a starting substrate, without considering the absolute orientation of the substrate).

As described above, in order to change the feature size of the Kelvin VIA without changing the mask, the present disclosure provides a manufacturing method by adjusting the etching process. To get the manufacturing method, all experiments were performed on TEL Tactras™ Vigus chamber, which is a typical capacitive coupled plasma (CCP) etcher with superimposed direct current (DC), with dual RF power with 40 MHz and 13 MHz applied at bottom electrode. The cross-sections of devices and critical dimension (CD) of devices of the experiments have been confirmed by transmission electron microscope (TEM) and CDSEM.

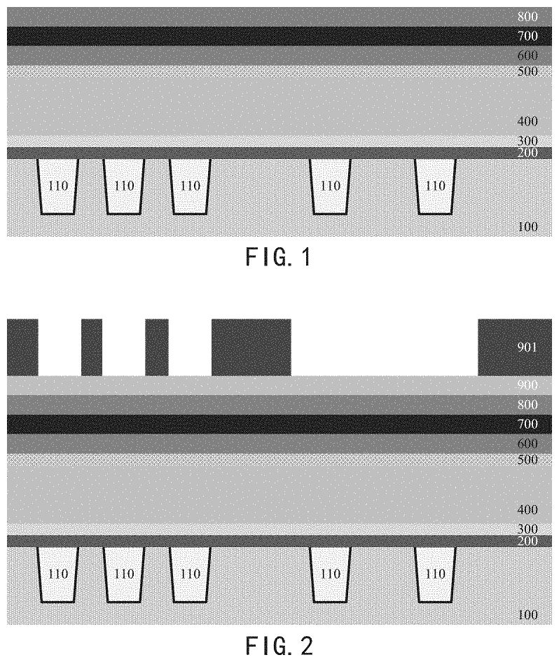

Please refer to FIGS. 1-8 to understand the manufacturing method of the present disclosure. FIGS. 1-8 are schematic views showing the structure of a semiconductor in a manufacturing process of the manufacturing method of the present disclosure.

The drawings are provided for illustration only and should not unduly limit the scope of the claims. Those skilled in the art will appreciate that there are many alternatives, and variations. One or more steps may be added, removed, repeated, rearranged, modified, replaced, and/or overlap depending on the implementation and this does not affect the scope of the claims.

As shown in FIG. 1, the substrate 100 and various thin film layers have been provided over the substrate 100. Specifically, a plurality of active areas 110 are formed in the substrate 100, and the active areas 110 are used to form a functional region of the semiconductor device. In the present disclosure, the active areas 110 need to be led out from the substrate 100 by forming VIAs. Above the substrate 100, an NDC layer 200, a TEOS layer 300, a dielectric layer 400, an NDC layer 500, a NFDARC layer 600, a hard mask layer 700, and an oxide layer 800 are formed.

Further, the back metal wire to be formed in the present disclosure and the back metal layer in which the VIA is located are formed by using the dielectric layer 400 as an intermediate dielectric layer, that is, the VIA formed by the present disclosure is to go throughout the dielectric layer 400.

Those skilled in the art will appreciate that the above-described manufacturing process for forming a dielectric layer on the front device layer, then etching the dielectric layer to form VIAs or trenches, and filling the VIAs or trenches with the metal dielectric is a damascene process. The manufacturing method of the present disclosure is constructed in a damascene process, but is different from the existing damascene process by improving the process therein.

With further reference to FIG. 2-4, FIGS. 2-4 show the etching of the hard mask layer of the trench. The back metal layer of the semiconductor device comprises VIA going throughout a dielectric layer to extract the devices located in the substrate or on the surface of the substrate, and trench to form the back metal interconnect wire. The manufacturing method of the present disclosure needs to form a portion of VIA first, then form a trench, and simultaneously complete etching of another portion of the VIA when forming the trench. Therefore, the manufacturing method provided by the present disclosure is constructed in the Damascus process of VIA First.

Although partial VIA needs to be formed first, at the beginning of the process step, a hard mask layer of trenches including the hard mask layer 700 shown in FIG. 1 needs to be formed first. The above-mentioned hard mask layer can be used as a photo-mask as a substitute for the photo-resist in the subsequent step of etching the trench. The hard mask layer 700 may be a metal mask layer, and further, the material may be TiN. Those skilled in the art should know that by providing a metal mask layer of TiN material, and also by providing a plurality of mask layers of different properties, such as NFDARC layer 600 and oxide layer 800, better line width control in subsequent trench etching can be realized.

FIG. 2 shows a patterned photo-resist layer 901 formed on the BARC layer 900. FIG. 3 illustrates etching process by using the patterned photo-resist layer 901 as a photo-mask to transfer the trench pattern downwards into the NFDARC layer 600. FIG. 4 shows a schematic view of hard mask layer with the trench pattern being formed after the BARC layer 900 and photo-resist layer 901 are removed.

Those skilled in the art will appreciate that the above patterning process may include photo-resist coating (e.g., spin coating), soft bake, photo-mask alignment, exposure, post-exposure bake, photo-resist development, rinsing, drying (e.g., hard roasting), other suitable processes, and/or combinations of the foregoing. Moreover, the above etching process can also be performed by existing or future processes, and details are not described herein again.

With further reference to FIG. 5, a barrier layer 910 has been formed as shown in FIG. 5 to protect the hard mask layer with pattern trench being formed from accidental etched when etching the VIAs. Further, a SIARC layer 911 for optimizing the photolithography effect and a photo-resist layer 912 with VIAs pattern on the surface thereof are formed over the barrier layer 910. The patterned photo-resist layer 912 defines the shape of the VIA.

As described above, Kelvin VIAs are through holes at the turning point, if the shape of the through hole is changed by changing the layout of the mask, the design of the parts adjacent to the Kelvin VIA needs to be changed accordingly, so the manufacturing cost is greatly increased. Therefore, the photo-mask used in patterning the patterned photo-resist layer 912 as shown in FIG. 5 is the same photo-mask as that of the prior art, that is, the present disclosure does not change the shape and feature size of the through hole by changing the mask design layout.

Please further refer to FIG. 6. FIG. 6 shows a schematic diagram of performing partial etching of VIA according to an etching pattern on the patterned photo-resist layer 912. In this step, most of the dielectric layer 400 has been etched away according to the etching pattern of the VIAs. Further, the etching process parameters used in the manufacturing method of the present disclosure include etching a portion of the VIA by using a gas combination containing CF4 gas playing the role of bringing out the product during the etching process. Further, in the gas combination containing CF4 gas used in this step, the proportion of CF4 is 20% to 35%, and in one embodiment the CF4 gas accounts for 28%. Those skilled in the art will appreciate that in the conventional process of etching VIAs, the ratio of CF4 to etching gas is about 12%. In the first etching step, the manufacturing method of the present disclosure can effectively reduce the amount of products remaining in the etching process and reduce the release rate of the polymer by increasing the ratio of the CF4 ratio to the total gas amount, to prepare for the subsequent steps of defining the appearance of the VIA and etching VIA.

Further, the above gas combination may further include other etching gases such as C4F8, O2, Ar, and the like. Those skilled in the art should know that the gas composition and the proportion of other gases of the above gas combination can be adjusted according to actual conditions, but it is necessary to ensure that the proportion of CF4 gas in the above gas combination used in the first etching step is 20%-35%, and in one embodiment 28%.

Please refer to FIG. 7. FIG. 7 shows a structural schematic view after a first etching process has been performed, a partial VIA is formed in the dielectric layer 400, and the barrier layer 900 is removed.

With further reference to FIG. 8, FIG. 8 shows a schematic diagram of performing VIA and trench etching in accordance with an etched pattern on the patterned hard mask layer. As shown in FIG. 8, a VIA going through the dielectric layer 400 has been formed, and the formed VIA exposes the active area 110 located in the substrate 100 to lead the active area 110 out.

The etching process parameters adopted in the above-mentioned steps of the manufacturing method of the present disclosure include etching the VIAs and the trenches by using a gas combination containing CF4 gas playing the role of bringing out the product during the etching process. Still further, in the gas combination containing CF4 gas used in this step, the proportion of CF4 is 25%-40%, and in one embodiment the ratio of the CF4 gas is 35%. It should be noted that in this step, the proportion of CF4 in the gas combination used in the method of the present disclosure is much larger than the proportion of CF4 gas in the gas combination used in the conventional etching VIA process. Moreover, it is further higher than the proportion of CF4 gas set in the first etching process of the manufacturing method of the present disclosure. Therefore, in this step, the feature size of the etched VIA can be increased due to the function of the CF4 gas of taking the product out.

Further, in the second etching process of the manufacturing method of the present disclosure, the etching process parameters used further include adjusting the dissociation power of the etching gas to be between 270-350 W. By reducing the dissociation power to reduce the ion bombardment energy, the etching ability of the VIA can be improved. In one embodiment, in this step, the dissociation power of the etching gas can be adjusted between 280-330 W, and within the above range, in one embodiment, the dissociation power of the etching gas can be adjusted to 300 W to balance etching ability and ability to take out residual products.

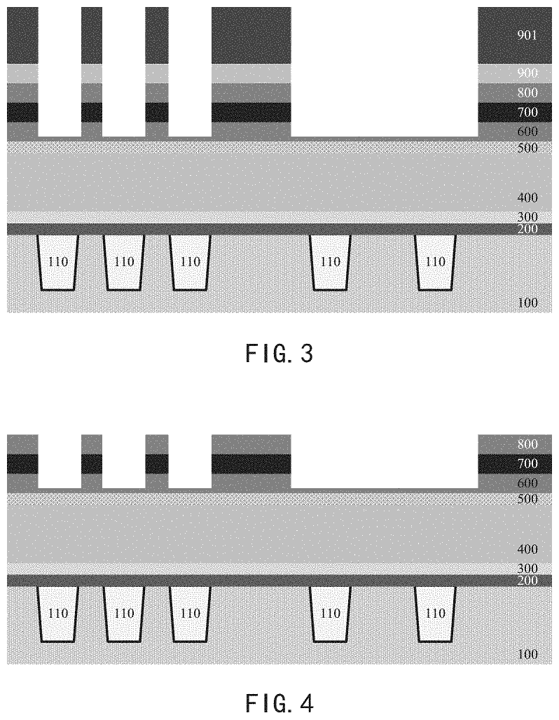

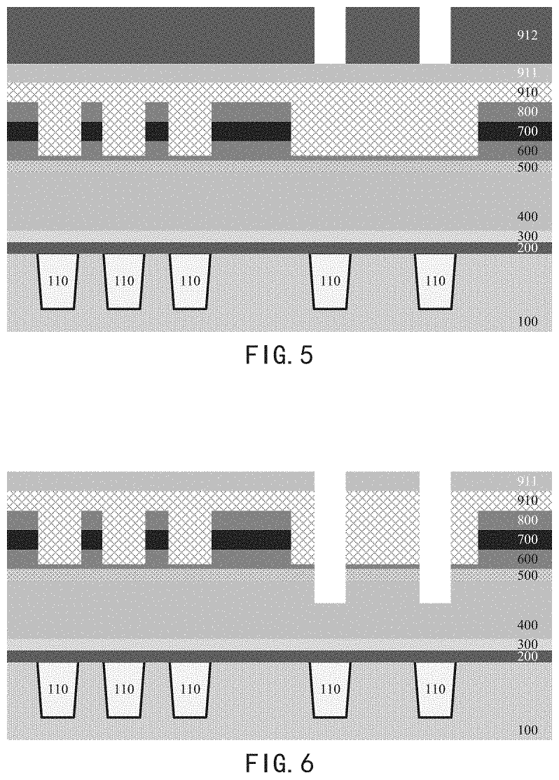

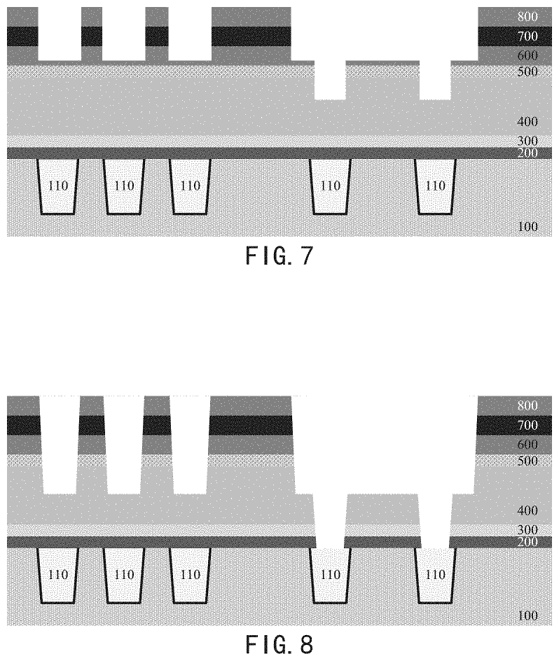

Please refer to FIG. 9A, FIG. 9B and FIG. 9C for the appearance of the VIAs formed by the manufacturing method of the present disclosure, and FIG. 9A shows a plan view of the VIA, FIG. 9B shows a cross-sectional view of the VIA of FIG. 9A in AA′ plane, and FIG. 9C shows a cross-sectional view of the VIA of FIG. 9A in BB′ plane.

As shown in FIG. 9, the medium grey portion in the figure extending in the Y direction is the back metal wire, that is, the schematic diagram of the trench. The dimension of the formed VIA (dark gray elliptical shape in the figure) in the Y direction is larger than the dimension in the X direction perpendicular to the Y direction. It can be understood that the cross section of the VIA may be an elliptical shape or shape similar to ellipse.

Since the formed Kelvin VIA is located above the trench, the appearance of the Kelvin VIA here is also subject to the patterning of the trench. As described above, the manufacturing method of the present disclosure defines a pattern of trenches by using a patterned hard mask layer, that is, a hard mask layer is formed in a light gray portion as in FIG. 9A, and thus, in the case of the VIA, under the first etching process and the second etching process condition of the present disclosure, since the X-direction is protected by the hard mask layer, the etching ability of the first etching process and the second etching process is improved in the Y direction. Referring to FIG. 9B and FIG. 9C together, it can be seen from FIG. 9B and FIG. 9C that the first etching process and the second etching process of the present disclosure can make the size of the finally formed VIA in the Y direction larger than the size in the X direction.

As described above, since the metal hard mask layer (which can be TiN material) is additionally provided, as a substitute for the photo-resist, to be a mask for the trench, the hard mask layer is more protective in the X direction. By using the first etching process and the second etching process of the present disclosure, the ratio of the first dimension in the Y direction of the formed VIA to the second dimension in the X direction can be in the range of 1.5-1.8.

Through experiments, even if a hard mask layer is not used, it is still possible to use the photo-resist having weak protection ability to achieve the ratio of the first dimension in the Y direction of the formed VIA to the second dimension in the X direction in the range of 1.2-1.5 by the first etching process and the second etching process provided by the present disclosure.

By the first etching process and the second etching process condition improved by the present disclosure, the size of the VIA in the extending direction of the back metal wire can be made larger than the dimension in direction perpendicular to the extending direction. Therefore, a short circuit between the VIA and other VIA or between the VIA and the back metal wire would not be caused, and the yield of the semiconductor device can be ensured.

At the same time, since the cross-sectional area of the cross-section of the VIA is increased, the impedance value of the metal medium in the VIA can be reduced, so that the performance of the semiconductor device can be effectively improved.

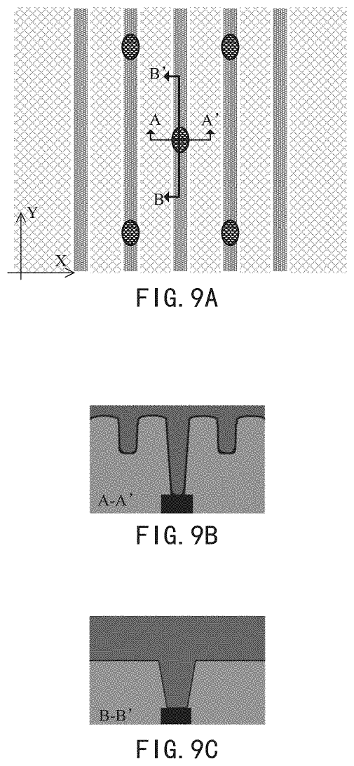

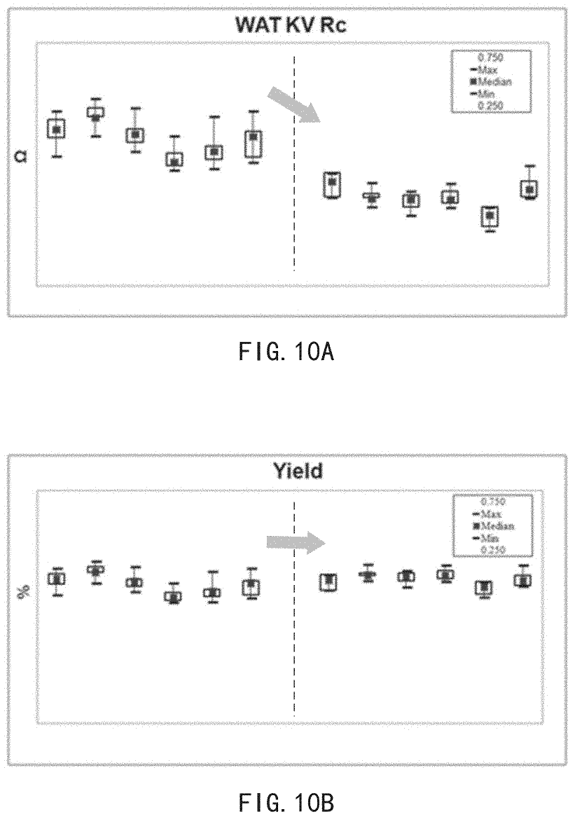

FIGS. 10A and 10B show the resistance characteristics of the above-described VIAs and the yield of the semiconductor device. As can be seen from FIG. 10A, the data on the left side of the broken line are the resistance value of the Kelvin VIA manufactured by the prior art, and the data on the right side of the broken line are the resistance value of the Kelvin VIA manufactured by the manufacturing method provided by the present disclosure. Through calculations, it was found that the resistance of the Kelvin VIA was effectively reduced by 15%.

As can be seen from FIG. 10B, the data on the left side of the broken line are the device yield of the semiconductor device manufactured by the prior art, and the data on the right side of the broken line are the device yield of the semiconductor device manufactured by the manufacturing method provided by the present disclosure. It can be found that the manufacturing method provided by the present disclosure can maintain the yield of the semiconductor device, that is, the manufacturing method provided by the present disclosure can reduce the Kelvin VIA resistance without adversely affecting device performance.

The present disclosure also provides a semiconductor structure formed by the above manufacturing method, the semiconductor structure including a VIA going throughout a dielectric layer in a height direction of the semiconductor structure, the VIA interconnecting a front device of the semiconductor structure and a back metal wire of the semiconductor structure, a first dimension of the cross section of the VIA orthogonal to the height direction in an extending direction of the back metal wire is larger than a second dimension in an direction vertical to the extending direction.

Further, the ratio of the first dimension to the second dimension is greater than 1.2.

Further, the ratio of the first dimension to the second dimension is 1.2-1.5.

In one embodiment, the ratio of the first dimension to the second dimension described above can be made 1.5-1.8 by using a metal hard mask layer during the etching process.

By the increase in the feature size of the VIA, the resistance of the metal medium located in the VIA can be lowered. And the cross-section of the VIA is kept in a dimension larger than the dimension in the other vertical direction, so that the short-circuiting between the VIA and the other VIA or the metal wire is not caused by the increase of the feature size, guaranteeing the yield of the semiconductor structure.

Although the present disclosure has been described with respect to certain exemplary embodiments, it will be apparent that various modifications and changes may be made to these embodiments without departing from the more general spirit and scope of the disclosure. Accordingly, the specification and the accompanying drawings are to be regarded in an illustrative rather than a restrictive sense.

It is to be understood that this description is not intended to explain or limit the scope or meaning of the claims. In addition, in the detailed description above, it can be seen that various features are combined together in a single embodiment for the purpose of simplifying the disclosure. The method of the present disclosure should not be interpreted as reflecting the intention that the claimed embodiments require more features than those expressly listed in each claim. Rather, as reflected by the appended claims, an inventive subject matter lies in being less than all features of a single disclosed embodiment. Therefore, the appended claims are hereby incorporated into the detailed description, with each claim standing on its own as a separate embodiment.

One embodiment or embodiments mentioned in this description is/are intended to be, combined with a particular feature, structure, or characteristic described in the embodiment, included in at least one embodiment of a circuit or method. The appearances of phrases in various places in the specification are not necessarily all referring to a same embodiment.

1. A method of manufacturing a semiconductor structure for forming a VIA going throughout a dielectric layer along a height direction of the semiconductor structure, the VIA being configured to electrically connect a front device to a back metal wire of the semiconductor structure and being characterized by a first feature size and a first resistance value, the method of manufacturing comprising:
providing a substrate, wherein an upper portion of the substrate is formed with the dielectric layer covering the substrate;
performing a first etching process in a position corresponding to the front device, the first etching process forms a partial VIA in an upper portion of the dielectric layer; and
performing a second etching process, the second etching process makes the partial VIA go throughout the dielectric layer in the height direction to expose the front device;
wherein the first feature size of the VIA is configured as a first dimension of the cross section of the formed VIA orthogonal to the height direction in an extending direction of the back metal wire is greater than a second dimension of the cross section in a direction vertical to the extending direction due to the first etching process and the second etching process; and
wherein the first feature size of the VIA is associated with the first resistance value of the VIA.

2. The manufacturing method of claim 1, wherein the first etching process comprises using a gas combination comprising CF4 gas, wherein the CF4 gas accounts for 20-35% of the gas combination.

3. The manufacturing method of claim 2, wherein the CF4 gas accounts for 28% of the gas combination.

4. The manufacturing method of claim 1, wherein the second etching process comprises setting the dissociation power of the etching gas to 270-350 W.

5. The manufacturing method of claim 4, wherein the set dissociation power is 280-330 W.

6. The manufacturing method of claim 4, wherein the dissociation of the set power 300 W.

7. The manufacturing method of claim 1, wherein said second etching process comprises using a gas combination comprising CF4 gas, wherein the CF4 gas accounts for 25-40% of the gas combination.

8. The manufacturing method of claim 7, wherein the CF4 gas accounts for 35% of the gas combination.

9. The manufacturing method of claim 1, wherein a ratio of the first dimension to the second dimension is greater than 1.2.

10. The manufacturing method of claim 9, wherein the ratio of the first dimension to the second dimension is 1.2-1.5.

11. The manufacturing method of claim 1, wherein, performing the second etching process further comprises forming a trench in an upper portion of the dielectric layer, wherein the back metal wire is formed in the trench; and
the manufacturing method further comprises forming a patterned hard mask layer on an upper surface of the dielectric layer before performing the second etching process, the patterned hard mask layer defining an etching pattern of the trench.

12. The manufacturing method of claim 11, wherein the hard mask layer is a metal mask, and/or the hard mask layer is made of TiN.

13. The manufacturing method of claim 11, wherein a ratio of the first dimension to the second dimension is 1.5-1.8.

14. A semiconductor structure including a VIA going throughout a dielectric layer in a height direction of the semiconductor structure, wherein the VIA is configured to electronically connect a front device of the semiconductor structure and a back metal wire of the semiconductor structure, wherein the VIA is characterized by a first feature size and a first resistance value, wherein the first feature size of the VIA being configured as a first dimension of the cross section of the VIA orthogonal to the height direction in an extending direction of the back metal wire is larger than a second dimension in a direction vertical to the extending direction, and wherein the first feature size of the VIA is associated with the first resistance value of the VIA.

15. The semiconductor structure of claim 14 wherein a ratio of the first dimension to the second dimension is greater than 1.2.

16. The semiconductor structure of claim 15, wherein the ratio of the first dimension to the second dimension is 1.2-1.5.

17. The semiconductor structure of claim 15, wherein the ratio of the first dimension to the second dimension is 1.5-1.8.

18. A method of manufacturing a semiconductor structure for forming a VIA going throughout a dielectric layer along a height direction of the semiconductor structure, the VIA being configured to electrically connect a front device to a back metal wire of the semiconductor structure and being characterized by a first feature size and a first resistance value, the method of manufacturing comprising:
providing a substrate, wherein an upper portion of the substrate is formed with the dielectric layer covering the substrate;
performing a first etching process in a position corresponding to the front device, the first etching process forms a partial VIA in an upper portion of the dielectric layer; and
performing a second etching process, the second etching process makes the partial VIA go throughout the dielectric layer in the height direction to expose the front device;
wherein the first feature size of the VIA is configured as a first dimension of the cross section of the formed VIA orthogonal to the height direction in an extending direction of the back metal wire is greater than a second dimension of the cross section in a direction vertical to the extending direction due to the first etching process and the second etching process;
wherein the first feature size of the VIA is associated with the first resistance value of the VIA; and
wherein the increase of the feature size of the VIA is configured to lower of the resistance value of the VIA while preventing the short-circuiting within the semiconductor structure.
